(19) United States
(12) Patent Application Publication
(10) Pub. No.: US 2025/0372437 A1
(43) Pub. Date: Dec. 4, 2025

(54) LIFT PIN ASSEMBLIES, SEMICONDUCTOR PROCESSING SYSTEMS INCLUDING LIFT PIN ASSEMBLIES AND METHODS OF TRANSFERRING SUBSTRATES IN SEMICONDUCTOR PROCESSING SYSTEMS USING LIFT PIN ASSEMBLIES

(71) Applicant: ASM IP Holding B.V., Almere (NL)

(72) Inventor: Christopher Cillie, Scottsdale, AZ (US)

(21) Appl. No.: 19/219,549

(22) Filed: May 27, 2025

Related U.S. Application Data
(60) Provisional application No. 63/654,698, filed on May 31, 2024.

(51) Int. Cl. H01L 21/687; H10N 30/20

(52) U.S. Cl. CPC H01L 21/68742; H10N 30/2027

(57) ABSTRACT

A lift pin assembly includes a lift pin body, two or more piezoelectric cells and a lead. The lift pin body includes a contact feature defined on a first end of the lift pin body and a fixation feature longitudinally opposite the contact feature. The two or more piezoelectric cells are stacked within the lift pin body between the fixation feature and the contact feature. The lead is electrically connected to the plurality of piezoelectric cells and extends to the external environment outside of the lift pin body to change the length of the lift pin body between a first length and a second length using a voltage applied to the lead. Semiconductor processing systems including the lift pin assemblies and substrate transfer methods are also described.

This application claims priority to U.S. Provisional Patent Application No. 63/654,698, filed May 31, 2024, the contents of which is incorporated herein by reference in its entirety.

### FIELD OF INVENTION

The present disclosure generally relates to material transfer, and more particularly to transferring material using solid-state electronic devices such as piezoelectric cells.

### BACKGROUND OF THE DISCLOSURE

Material handling is commonly accomplished using mechanical devices like forks or tines as well as various types of lifting devices, like cranes and derricks. In the case of semiconductor device fabrication, material handling is generally accomplished using robot-driven lifts, such as during the fabrication of semiconductor devices. In the case of semiconductor device fabrication, substrate transfer may be accomplished using end effectors and lift pins. End effectors are generally driven by robots and typically carry substrates between various locations within the semiconductor processing system. Lift pins are generally employed to transfer substrates between structures within semiconductor processing systems, such as between end effectors and stages employed for substrate processing and between end effectors and intermediate storage locations within the semiconductor processing systems. Movement of lift pins is typically accomplished in semiconductor processing systems mechanically, requiring that mechanical actuation devices and/or mechanical clearances be maintained within the semiconductor processing system.

Such methods and systems have generally been considered suitable for their intended purpose. However, there remains a need in the art for improved lift pin assemblies, semiconductor processing systems including lift pin assemblies and substrate transfer methods. The present disclosure provides a solution to this need.

### SUMMARY OF THE DISCLOSURE

A lift pin assembly is provided. The lift pin assembly includes a lift pin body, two or more piezoelectric cells and a lead. The lift pin body includes a contact feature defined on a first end of the lift pin body and a fixation feature longitudinally opposite the contact feature. The two or more piezoelectric cells are stacked within the lift pin body between the fixation feature and the contact feature. The lead is electrically connected to the plurality of piezoelectric cells and extends to the external environment outside of the lift pin body to change the length of the lift pin body between a first length and a second length using a voltage applied to the lead.

In addition to one or more of the features described above, or as an alternative, further examples of the lift pin assembly may include that the lift pin body is linear along an entirety of the length of the lift pin body between the contact feature and the fixation feature.

In addition to one or more of the features described above, or as an alternative, further examples of the lift pin body may include the lift pin body is arcuate, at least in part, between the contact feature and the fixation feature. The lift pin body may be helical at least in part between the contact feature and the fixation feature.

In addition to one or more of the features described above, or as an alternative, further examples of the lift pin body may include the lift pin body is corrugated.

In addition to one or more of the features described above, or as an alternative, further examples of the lift pin assembly may include that the lift pin body further includes a first linear portion, an arcuate portion extending from the first linear portion, and a second linear portion. The second linear portion of the lift pin body may extend from the arcuate portion and be parallel to the first linear portion. The second linear portion of the lift pin body may be corrugated along at least a segment of its length and may be formed from a shape memory alloy.

In addition to one or more of the features described above, or as an alternative, further examples of the lift pin assembly may include that the two or more piezoelectric cells may be longitudinally stacked within the lift pin body.

In addition to one or more of the features described above, or as an alternative, further examples of the lift pin assembly may include that the two or more axially adjacent piezoelectric cells may be coupled by a hinge.

In addition to one or more of the features described above, or as an alternative, further examples of the lift pin assembly may include that the two or more piezoelectric cells may be formed from a crystalline material, a ceramic material and/or a polymeric material.

In addition to one or more of the features described above, or as an alternative, further examples of the lift pin assembly may include that the two or more of piezoelectric cells are electrically coupled in parallel between the lead and a return terminal.

In addition to one or more of the features described above, or as an alternative, further examples of the lift pin assembly may include that the contact feature includes silicon nitride (SiN), aluminum oxide (Al₂O₃), quartz and/or diamond-like carbon.

A semiconductor processing system is provided. The semiconductor processing system includes a chamber body, a substrate support, a lift pin assembly as described above, and a controller. The chamber body has a hollow interior. The substrate support is arranged within the interior of the chamber body and defining a lift pin aperture therethrough. The lift pin assembly is arranged (at least in part) within the lift pin aperture. The controller operably couples the voltage source to the lift pin assembly and is responsive to instructions in two or more program modules recorded on a non-transitory machine-readable medium included in a memory to apply a predetermined first voltage to the lead of the lift pin assembly, change the length of the lift pin body from a first length using the predetermined first voltage applied to the lead of the lift pin assembly, apply a predetermined second voltage to the lead of the lift pin assembly, and change the length of the lift pin body to a second length using the predetermined second voltage applied to the lead of the lift pin assembly.

In addition to one or more of the features described above, or as an alternative, further examples of the semiconductor processing system may include that the chamber body is a loadlock chamber included in the semiconductor processing system. The loadlock chamber may be configured for transfer of a substrate between fluidly separated environments within the semiconductor processing system.

In addition to one or more of the features described above, or as an alternative, further examples of the semiconductor processing system may include that the chamber body is a transfer chamber included in the semiconductor processing system. The transfer chamber may be configured for transferring a substrate between substrate transfer modules of the semiconductor processing system.

In addition to one or more of the features described above, or as an alternative, further examples of the semiconductor processing system may include that the chamber body is a deposition chamber included in the semiconductor processing system. The deposition chamber may be configured to deposit a material layer onto a substrate.

In addition to one or more of the features described above, or as an alternative, further examples of the lift pin assembly may include that the chamber body is an etch chamber included in the semiconductor processing system. The etch chamber may be configured to remove material from one or more of the substrate and a material layer deposited onto the substrate, for example using a dry etch technique.

In addition to one or more of the features described above, or as an alternative, further examples of the semiconductor processing system may include the lift pin assembly is one of two or more lift pin assemblies arranged within the chamber body and respective lift pin apertures defined within the substrate support. The substrate support may be a transfer stage, a chill plate, a heater, or a susceptor included in the semiconductor processing system.

A substrate transfer method is provided. The method includes, at a lift pin assembly as described above, applying a predetermined first voltage to the lead of the lift pin assembly, changing the length of the lift pin body from a first length using the predetermined first voltage applied to the lead of the lift pin assembly, applying a predetermined second voltage to the lead of the lift pin assembly, and changing the length of the lift pin body to a second length using the predetermined second voltage applied to the lead of the lift pin assembly.

In addition to one or more of the features described above, or as an alternative, further examples of the method may include seating the substrate on a substrate support arranged within a chamber body of a semiconductor processing system during change of the length of the lift pin body from the first length to the second length.

In addition to one or more of the features described above, or as an alternative, further examples of the method may include that the chamber body may be a deposition chamber configured to deposit a material layer onto a substrate. The method may further include depositing a material layer onto the substrate while the predetermined second voltage is applied to the lead.

In addition to one or more of the features described above, or as an alternative, further examples of the method may include that the substrate support may be an etch chamber configured to remove material from a substrate. The method may further include removing material from the substrate while the predetermined second voltage is applied to the lead.

In addition to one or more of the features described above, or as an alternative, further examples of the method may include that the substrate support may be a chill plate configured to chill a substrate seated on the chill plate. The method may further include chilling the substrate on the chill plate while the predetermined second voltage is applied to the lead.

In addition to one or more of the features described above, or as an alternative, further examples of the method may include that the substrate support may be a heater configured to heat the substrate. The method may further include heating the substrate while the predetermined second voltage is applied to the lead.

In addition to one or more of the features described above, or as an alternative, further examples of the method may include may include that the lift pin assembly is arranged within a loadlock chamber body. Prior to applying the predetermined second voltage to the lead, the substrate may be supported above the lift pin assembly by driving a first end effector carrying the substrate into the loadlock chamber body such that applying the predetermined second voltage to the lift pin assembly thereafter causes the substrate to transfer from the first end effector to the contact feature of the lift pin assembly. The first end effector may then be withdrawn from the loadlock chamber body, a second end effector driven into the loadlock chamber body, and the voltage applied to the lead changed from the predetermined second voltage such that further change in the length of the lift pin body transfers the substrate from the contact feature to the second end effector.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a cross-sectional side view of a semiconductor processing system with a lift pin assembly in accordance with the present disclosure, schematically showing the lift pin assembly around within a chamber electrically coupled to a voltage source;

FIG. 2 is a cross-sectional side view of a portion of a semiconductor processing system according to an example of the present disclosure, showing the lift pin assembly arranged within a deposition chamber to seat and unseat a substrate from a substrate support using voltages applied to piezoelectric cells arranged within the lift pin assembly;

FIG. 3 is a cross-sectional side view of the lift pin assembly of FIG. 1 according to a first example of the present disclosure, schematically showing a lift pin body with a linear shape having a first length when a predetermined first voltage is applied to piezoelectric cells arranged within the lift pin body;

FIG. 4 is a cross-sectional side view of the lift pin assembly of FIG. 3 according to the first example of the present disclosure, schematically showing the lift pin body lengthening to a second length when a predetermined second voltage applied to the piezoelectric cells arranged within the lift pin body;

FIG. 5 is a cross-sectional side view of the lift pin assembly of FIG. 1 according to a second example of the present disclosure, schematically showing a lift pin body with an arcuate segment coupling first and second linear segments having a first length when a predetermined first voltage is applied to piezoelectric cells arranged within the lift pin body;

FIG. 6 is a cross-sectional side view of the lift pin assembly of FIG. 5 according to the second example of the present disclosure, schematically showing the lift pin body having a second length when a predetermined second voltage is applied to the piezoelectric cells arranged within the lift pin body;

FIG. 7 is a plan view of the lift pin assembly of FIG. 1 according to a third example of the present disclosure, schematically a lift pin body having a coiled or helical segment and piezoelectric cells arranged within the lift pin body;

FIGS. 8 and 9 are a cross-sectional side views of the lift pin assembly of FIG. 7 according to the third example of the disclosure, schematically showing first and second lengths of the linear segment of the lift pin body when first and predetermined second voltages are applied to the piezoelectric cells arranged within the lift pin body, respectively;

FIGS. 10 and 11 are cross-sectional side views of the lift pin assembly of FIG. 1 according to a fourth example of the disclosure, schematically showing a first length and a second length of a lift pin body defined when a first voltage and a predetermined second voltage are applied to piezoelectric cells arranged within the lift pin body and coupled to one another by a plurality of hinges, respectively; and

FIGS. 12-14 are a block diagram of a substrate transfer method according to the present disclosure, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

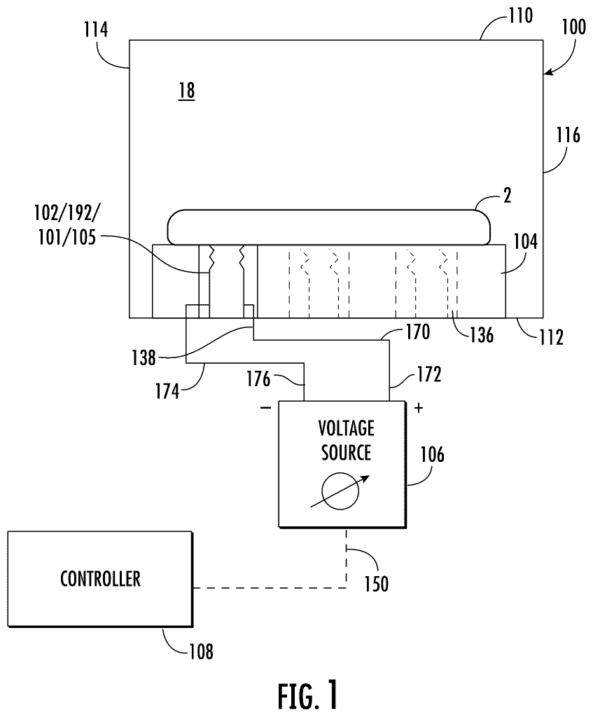

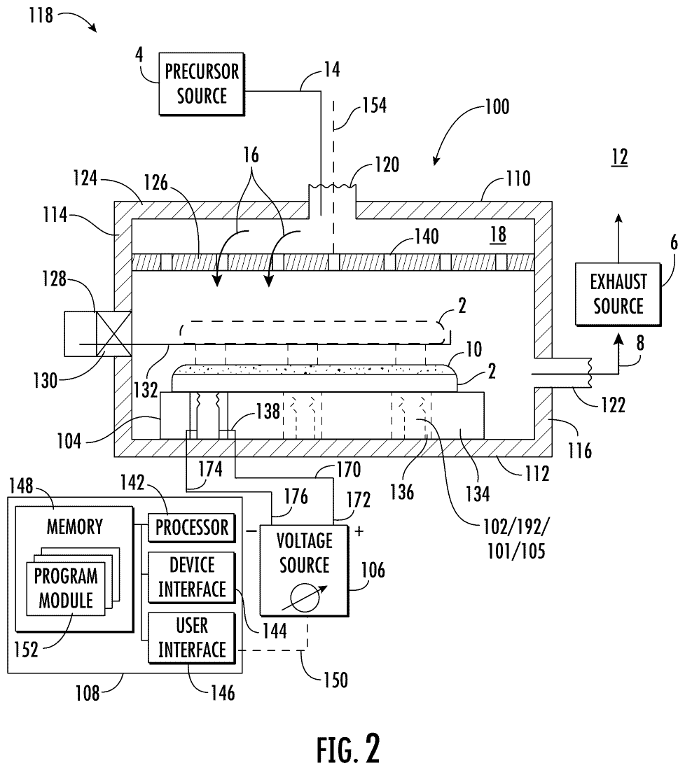

Reference will now be made to the drawings wherein like reference numerals identify similar structural features or aspects of the subject disclosure. For purposes of explanation and illustration, and not limitation, a partial view of an example of a chamber including a lift pin assembly in accordance with the present disclosure is shown in FIG. 1 and is designated generally by reference character 100. Other examples of lift pin assemblies, semiconductor processing systems and chambers including lift pin assemblies, and substrate transfer methods in accordance with the present disclosure, or aspects thereof, are provided in FIGS. 2-14, as will be described. The systems and methods of the present disclosure may be used for transferring substrates within semiconductor processing systems employed for depositing material layers onto substrates and/or removing material from substrates, such as during the fabrication of memory and logic semiconductor devices using atomic layer deposition and chemical vapor deposition techniques, though the present disclosure is not limited to the fabrication of any particular type of semiconductor device or to any particular semiconductor device fabrication operation in general.

Referring to FIG. 1, a chamber body 100 including a lift pin assembly 102 is shown. The chamber body 100 includes the lift pin assembly 102 a substrate support 104, a variable voltage source 106 and a controller 108. The chamber body 100 has an upper wall 110, a lower wall 112, a first sidewall 114 and a second sidewall 116. The upper wall 110 extends between the first sidewall 114 and the second sidewall 116. The lower wall 112 is similar to the upper wall 110 of the chamber body 100 and is additionally spaced apart from the upper wall 110 of the chamber body 100 by a hollow interior 18 of the chamber body 100. The substrate support 104 is arranged within the hollow interior 18 of the chamber body 100 and is configured to seat thereon a substrate 2, for example during transfer of the substrate between chambers of a semiconductor processing system. The lift pin assembly 102 is arranged (at least in part) within the substrate support 104, and configured to seat and unseat the substrate 2 from the substrate support 104 using a voltage applied to the lift pin assembly 102 by the variable voltage source 106. In this respect it is contemplated that the variable voltage source 106 is electrically connected to the lift pin assembly 102, operably associated with the controller 108, and configured to apply a first predetermined voltage and a second predetermined voltage to the lift pin assembly to elongate and shorten the lift pin assembly according to the voltage applied to the lift pin assembly 102.

In certain examples of the present disclosure the chamber body 100 may be a chamber body of a loadlock chamber of a semiconductor processing system. In accordance with certain examples, the chamber body 100 may be a chamber body of a transfer chamber of a semiconductor processing system, for example of transfer chamber coupling fluidly communicative environments coupled by the chamber body 100. It is also contemplated that the chamber body 100 may be a chamber body of a deposition chamber or an etch chamber of a semiconductor processing system. In certain examples of the present disclosure the substrate support 104 may be a chill plate, such as a chill plate seated within a loadlock chamber of a semiconductor processing system. In accordance with certain examples of the disclosure, the substrate support 104 may be a heater, such as a heater seated within a loadlock chamber or a deposition chamber of a semiconductor processing system. It is also contemplated that the substrate support 104 may be a transfer stage or a susceptor seated within a transfer module or a deposition module of a semiconductor processing system and remain within the scope of the present disclosure. As shown and described herein the lift pin assembly 102 is one of a plurality of lift pin assemblies 102, e.g., three (3) lift pin assemblies, slidably received in the substrate support 104. As will be appreciated by those of skill in the art in view of the present disclosure, fewer or additional lift pins may be received within a substrate support and remain within the scope of the present disclosure.

As used herein, the term “substrate” may refer to any underlying material or materials, including any underlying material or materials that may be modified, or upon which, a device, a circuit, or a film may be formed. A “substrate” may be continuous or non-continuous; rigid or flexible; solid or porous; and combinations thereof. A substrate may be in any form, such as a powder, a plate, or a workpiece. A substrate may be made from semiconductor materials, including, for example, silicon (Si), silicon germanium (SiGe), silicon oxide (SiO₂), gallium arsenide (GaAs), gallium nitride (GaN) and silicon carbide (SiC). As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

With reference to FIG. 2, a semiconductor processing system 118 is shown according to an example of the present disclosure. In the illustrated example the semiconductor processing system 118 includes the chamber body 100, the controller 108, a precursor source 4, and exhaust source 6. The chamber body 100 defines an inlet port 120 and an exhaust port 122. The exhaust port 122 is fluidly coupled to the exhaust source 6 by an exhaust conduit 8 and is configured to provide the flow of residual precursor and/or reaction products issued by the chamber body 100 during deposition of the material layer 10 onto the substrate 2 to an external environment 12 outside the semiconductor processing system 118. The inlet port 120 of the chamber body 100 is fluidly coupled to the precursor source 4 by a precursor supply conduit 14 and is configured to receive therethrough the flow of a material layer precursor 16. It is contemplated that the chamber body 100 may be formed from a metallic material 124. In certain examples, the metallic material 124 may include aluminum, such a low copper content aluminum alloy. In accordance with certain examples, the metallic material 124 may include a stainless steel material, such as a low copper content stainless steel alloy.

The precursor source 4 is coupled to the chamber body 100 by the precursor supply conduit 14, includes the material layer precursor 16 and is configured to communicate a flow of the material layer precursor 16 to the chamber body 100. In certain examples, the precursor source 4 may be configured to communicate one or more silicon-containing material layer precursor within the material layer precursor 16 communicated to the chamber body 100. Examples of suitable material layer precursors include non-chlorinated silicon-containing material layer precursors such as silane (SiH₄) and disilane (Si₂H₆) as well as chlorinated silicon material layer precursors like dichlorosilane (H₂SiCl₂) and trichlorosilane (HCl₃Si). In accordance with certain examples, the precursor source 4 may be configured to communicate a dopant-containing material layer precursor and/or an alloying constituent within the material layer precursor 16 to the chamber body 100. Examples of suitable dopant-containing material layer precursors include n-type dopant-containing material layer precursors, such as compounds containing phosphorous (P) or arsine (As), as well as n-type dopant-containing material layer precursors like compounds containing boron (B); examples of suitable alloying constituents include germanium-containing compounds, such as germane (GeH₄) by way of non-limiting example.

It is contemplated that the precursor source 4 may be configured to communicate an etchant to the chamber body 100, which may be co-flowed with the material layer precursor 16 or provided as a separate flow to the chamber body 100. Examples of suitable etchants include halogen-containing compounds such as hydrochloric (HCl) acid and chlorine (Cl₂) gas as well as fluorine-containing compounds like hydrofluoric (HF) acid. It is also contemplated that the precursor source 4 may be configured to communicate a diluent or carrier fluid (e.g., a gas) to the chamber body 100. For example, the precursor source 4 may be configured to communicate one or more of hydrogen (H₂) gas, nitrogen (N₂) gas, a noble gases, or a mixtures including one or more of the aforementioned gases. The carrier or diluent fluid may be communicated to the chamber body 100 with the material layer precursor 16 or separately, such as a purge fluid flow.

In the illustrated example the chamber body 100 has a downflow architecture and in this respect includes a gas distribution plate 126, which may be a showerhead, fluidly coupling the inlet port 120 of the chamber body 100 to the exhaust port 122 of the chamber body 100. In illustrated example a loadlock chamber 128 is further coupled to the chamber body 100 by a gate valve 130, for example through an intervening substrate transfer module, and a substrate transfer robot with an end effector 132 is further arranged outside of the chamber body 100 and in selective communication with the hollow interior 18 of the chamber body 100 through the gate valve 130.

The gas distribution plate 126 is fixed within the hollow interior 18 of the chamber body 100 and fluidly couples the inlet port 120 of the chamber body 100 to the exhaust port 122 of the chamber body 100. The gas distribution plate 126 further defines therethrough a plurality of showerhead apertures 140 and may be positioned at a location proximal to the upper wall 110 of the chamber body 100 to communicate a flow of the material layer precursor 16 received from the inlet port 120 to the substrate 2 when seated on the substrate support 104. It is contemplated that the substrate support 104 be arranged within the hollow interior 18 of the chamber body 100 and at a location whereat the gas distribution plate 126 fluidly couples the inlet port 120 to substrate support 104, and may be formed from a bulk metallic material like stainless steel or a bulk ceramic material such as aluminum nitride. It is further contemplated that the substrate support 104 define therein one or more lift pin aperture 136, and that the lift pin assembly 102 be slidably received (at least in part) within the lift pin aperture 136. The lift pin assembly 102 is in turn electrically connected to the variable voltage source 106, for example by a lead 138 passing through the chamber body 100 and into the external environment 12.

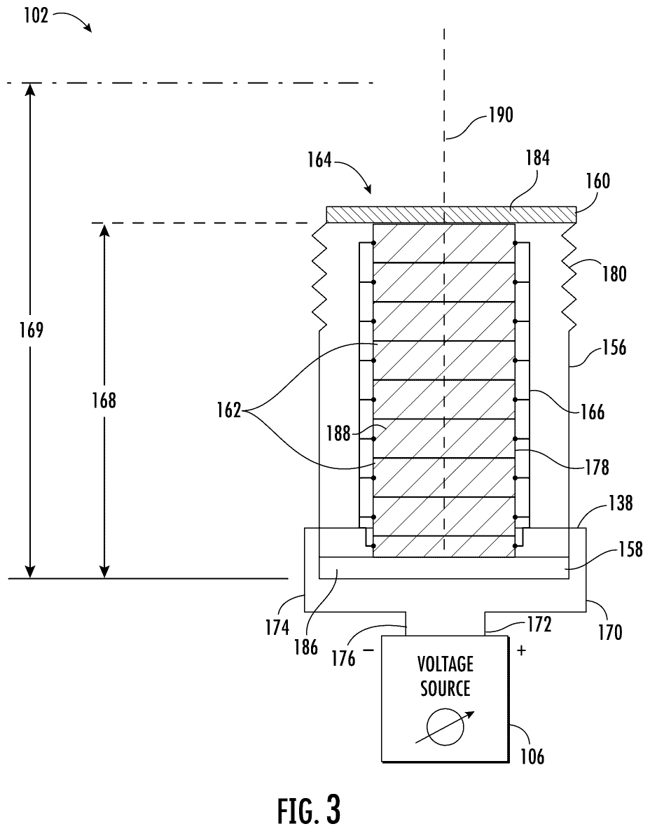

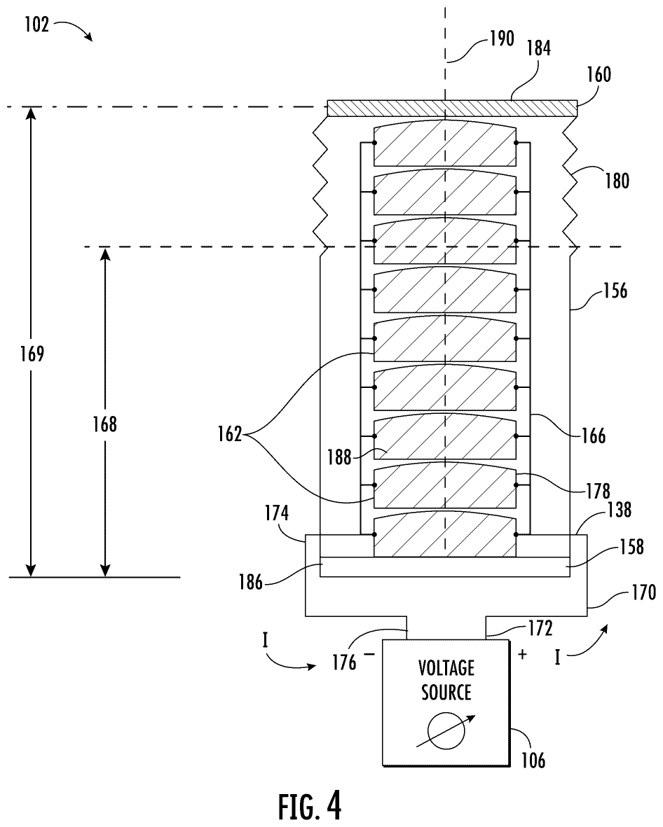

As shown in solid line and dashed line in FIG. 2, the lift pin assembly 102 may have a first length 168 (shown in FIG. 3) or a second length 169 (shown in FIG. 4) according to magnitude of voltage applied to the lift pin assembly 102 by the variable voltage source 106. In this respect it is contemplated that the lift pin assembly 102 cooperate with the substrate transfer robot and end effector 132 to seat the substrate 2 over substrate support 104[?] prior to deposition of the material layer 10 onto the substrate 2 and unseat the substrate 2 from the substrate support 104 subsequent to deposition of the material layer 10 onto the substrate 2. For example, a first predetermined voltage may be applied to the lift pin assembly 102 such that tips of the lift pin assembly 102 recess or withdraw into the one of the plurality of lift pin apertures 136 receiving the lift pin assembly 102. The gate valve 130 may then open and the substrate transfer robot advance the end effector 132 carrying the substrate 2 into the hollow interior 18 of the chamber body 100. A second predetermined voltage may then be applied to the lift pin assembly 102. Responsive to change of voltage applied to the lift pin assembly 102 from the first predetermined voltage to the second predetermined voltage, the lift pin assembly 102 may elongate from the first length 168 to the second length 169, elongation of the lift pin assembly 102 causing the lift pin assembly 102 to protrude from the lift pin aperture 136 and the substrate 2 to transfer from the end effector 132 to the lift pin assembly 102. The substrate transfer robot may then withdraw the end effector 132 from the hollow interior 18 of the chamber body 100, the gate valve 130 closed, and voltage applied to the lift pin assembly 102 changed from the second predetermined voltage to the first predetermined voltage such that the lift pin assembly 102 retracts (or withdraws) into the substrate support 104, the substrate 2 seating on the substrate support 104 as the lift pin assembly 102 withdraws into the substrate support 104. As will be appreciated by those of skill in the art in view of the present disclosure, unseating of the substrate 2 may be accomplished by again changing voltage applied to the lift pin assembly 102. Notably, seating and unseating may be accomplished without a mechanical actuator or an electrical motor, simplifying arrangement of the semiconductor processing system 118 and limiting (or eliminating) the need to service and maintain such devices. To further advantage, substantially all the lift pin assembly 102 may be packaged within the substrate support 104, limiting sized of the hollow interior 18 of the chamber body 100 and commensurately increasing throughput owing to corresponding reducing in volume requiring evacuation.

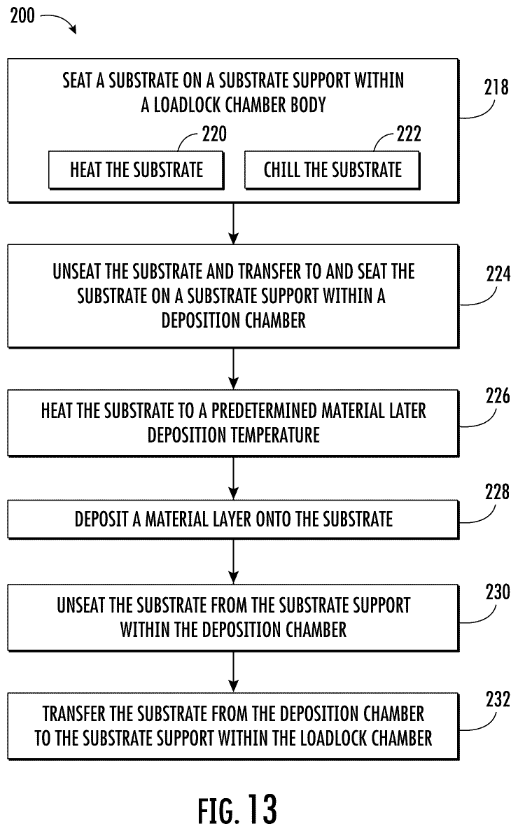

Operation of the lift pin assembly 102 may be controlled by the controller 108. In this respect it is contemplated that the controller 108 be operably coupled to one or more element of the chamber body 100, e.g., the variable voltage source 106, to control the voltage applied to the lift pin assembly 102 during seating and unseating of the substrate 2. In this respect the controller 108 may include a processor 142, device interface 144, a user interface 146 and a memory 148. The device interface 144 may couple the controller 108 to the lift pin assembly 102 via the wired or wireless link 150 and/or other elements of the semiconductor processing system 118 (shown in FIG. 1). The processor 142 is coupled to the device interface 144, and is operably coupled to the user interface 146 to receive user input and/or provide user output therethrough and is disposed in communication with the memory 148. The memory 148 includes a non-transitory machine-readable medium having a plurality of program modules 152 recorded thereon containing instructions that, when read by the processor 142, cause the processor 142 execute certain operations. Among the operations are operations of a material layer deposition method 200 (shown in FIG. 13), as will be described. Although shown and described herein as having a specific architecture, it is to be understood and appreciated that the controller 108 can have different architectures in other examples of the present disclosure (e.g., a distributed computing architecture), and remain within the scope of the present disclosure.

In the illustrated example, the lift pin assembly 102 is shown unseating the substrate 2 from the substrate support 104 following the deposition of a material layer 10 onto the substrate 2. Following the deposition of the material layer 10, a second voltage is applied to the lead 138 of the lift pin assembly 102 lengthening the lift pin assembly 102 and unseating the substrate 2 from the substrate support 104. The substrate transfer robot with an end effector 132 is shown originating from the loadlock chamber 128 and preparing to unseat the substrate 2 from the lift pin assembly 102. After the substrate transfer robot with an end effector 132 unseats the substrate 2 from the lift pin assembly 102, a first voltage is applied to the lead 138 of the lift pin assembly 102 shortening the lift pin assembly 102.

In an alternative example, the substrate transfer robot with an end effector 132 is shown preparing to seat the substrate 2 onto the substrate support 104. The first voltage is applied to the lead 138 of the lift pin assembly 102 resulting in the lift pin assembly 102 making contact with the underside of the substrate 2. The substrate transfer robot with an end effector 132 would then be retracted through the gate valve 130, and a second voltage is applied to the lead 138 of the lift pin assembly 102 resulting in the substrate 2 to be seated on the substrate support 104, where a material layer 10 may be deposited. When seated, the central point of the substrate 2 will align with the center axis 154 of the chamber body 100.

With reference to FIGS. 3 and 4, the lift pin assembly 102 is shown according to an example of the disclosure. As shown in FIG. 3, the lift pin assembly 102 includes a lift pin body 156 having a fixation feature 158 and a contact feature 160, a plurality of piezoelectric cells 162, and the lead 138. The contact feature 160 is defined on a first end 164 of the lift pin body 156, is connected to the lift pin body 156, and is coupled to the fixation feature 158 by the lift pin body 156. The lift pin body 156 extends between the fixation feature 158 and the contact feature 160, couples the contact feature 160 to the fixation feature 158, and is contains the plurality of piezoelectric cells 162. The fixation feature 158 is longitudinally opposite the contact feature 160 and is configured to fix the lift pin assembly 102 relative to the chamber body 100 (shown in FIG. 1). In this respect it is contemplated that the fixation feature may include threads or a key feature to fix the fixation feature 158 and second end of the lift pin body 156 relative to the substrate support 104 (shown in FIG. 1) while the first end 164 of the lift pin body 156 remains free relative to the substrate support 104.

The contact feature 160 of the lift pin body 156 is formed from a contact feature material 184 and is configured to make contact with the underside of the substrate 2 during seating and unseating of the substrate 2 from the substrate support 104. The contact feature material 184 may in turn may be selected such that it may withstand the environment found within the chamber body 100. Alternatively (or additionally) the contact feature material 184 may be selected to separate a material forming the lift pin body 156 potentially incompatible with the substrate 2 material, such a copper-containing metals. The contact feature material 184 may further be chosen so that the contact feature does not scratch or damage the underside of the substrate 2 during the seating and unseating of the substrate 2 from the substrate support 104, which could otherwise scratch or damage an underside of the substrate 2 and/or cause particles to be introduced into the hollow interior 18 (shown in FIG. 1) of the chamber body 100 (shown in FIG. 1), leading to contamination. In certain examples of the present disclosure the contact feature 160 may be fixed to a first end 164 of the lift pin body 156 and in this respect may be deposited onto the first end 164 of the lift pin body 156. In accordance with certain examples, the contact feature 160 may be a discrete structure slidably received on the first end 164 of the lift pin body 156, and may be formed as a sleeve member. Examples of suitable contact feature materials include silicon nitride (SiN), aluminum oxide (Al₂O₃), quartz and diamond-like carbon.

The fixation feature 158 is longitudinally opposite the contact feature 160 and is coupled to the contact feature 160 by the lift pin body 156. The fixation feature 158 is further formed from a fixation feature material 186, which may be made of a metallic material such as an aluminum alloy or a stainless steel material. It is contemplated that the fixation feature 158 fix the lift pin assembly 102 within the chamber body 100, the fixation feature 158 being stationary relative to the chamber body 100 (shown in FIG. 1) and/or the substrate support 104 (shown in FIG. 1), the contact feature 160 being movable relative to the fixation feature 158 within the hollow interior 18 of the chamber body 100. In the illustrated example, the fixation feature 158 affixes the lift pin assembly 102 to the lower wall 112 (shown in FIG. 1) of the chamber body 100. As will be appreciated by those of skill in the art in view of the present disclosure, the fixation feature 158 may affix the lift pin assembly 102 to the first sidewall 114 (shown in FIG. 1), the second sidewall 116 (shown in FIG. 1), or the upper wall 110 (shown in FIG. 1) of the chamber body 100 and remain within the scope of the present disclosure.

The lift pin body 156 extends between the contact feature 160 and the fixation feature 158 such that the contact feature 160 is longitudinally opposite fixation feature 158. It is contemplated that the lift pin body 156 be formed from a metallic material, such as an aluminum alloy or a stainless steel, as well as a shape memory alloy. The lift pin body 156 may further be corrugated along a least a portion of its length or be non-corrugated, at least in part, along a length of the lift pin body 156. In this respect it is contemplated that the lift pin body 156 may include a corrugated portion 180 intermediate the contact feature 160 the fixation feature 158, for example extending only partially along a length of the lift pin body 156 and proximate one of the contact feature 160 and the fixation feature 158. The corrugated portion 180 may in turn be configured to change in length responsive to expansion and contraction of the plurality of piezoelectric cells 162. Expansion and contraction of plurality of piezoelectric cells 162 may in turn be responsive to change in voltage applied to the lift pin assembly 102, the lift pin body 156 elongating responsive to increase in voltage and shortening responsive to voltage decrease, providing control of length of the lift pin body 156 according to voltage applied to the lift pin body 156. The lengthening or shortening of the lift pin body 156 may be enabled by the corrugated portion 180, which may in turn be formed from a shape memory alloy. As will be appreciated by those of skill in the art in view of the present disclosure, examples having the corrugated portion 180 proximate the contact feature 160 promote orthogonality of the lift pin body 156 relative to the substrate support 104. As will also be appreciated by those of skill in the art in view of the present disclosure, examples having the corrugated portion 180 proximate the fixation feature 158 may limit tendency of the lift pin assembly 102 to shed particles, for example in deposition chambers where substrate curl may expose the lift pin body 156 to material layer precursor.

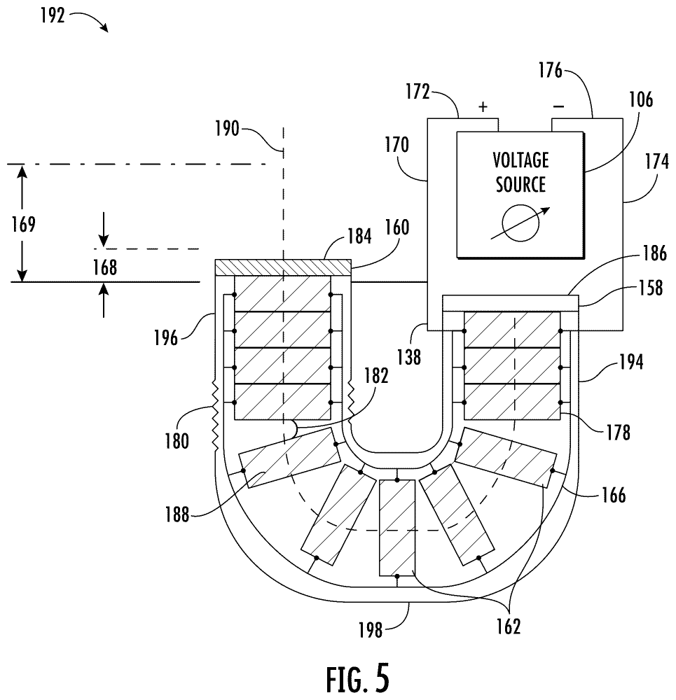

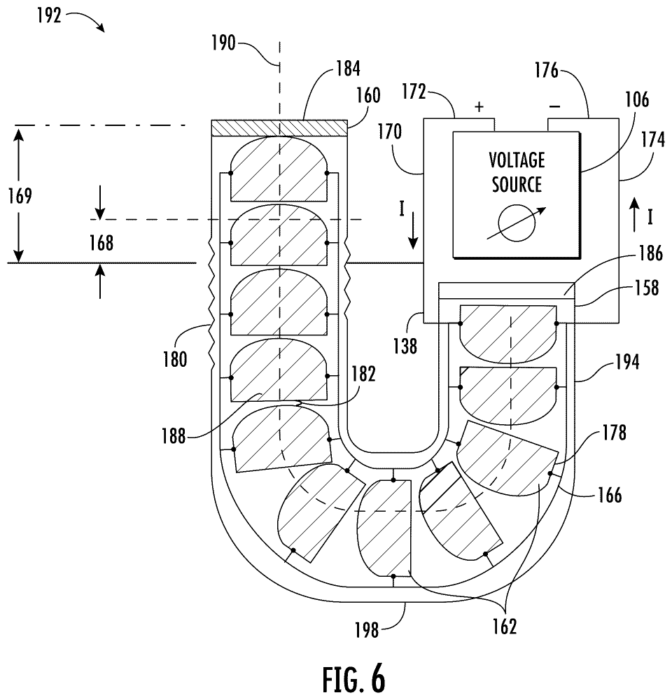

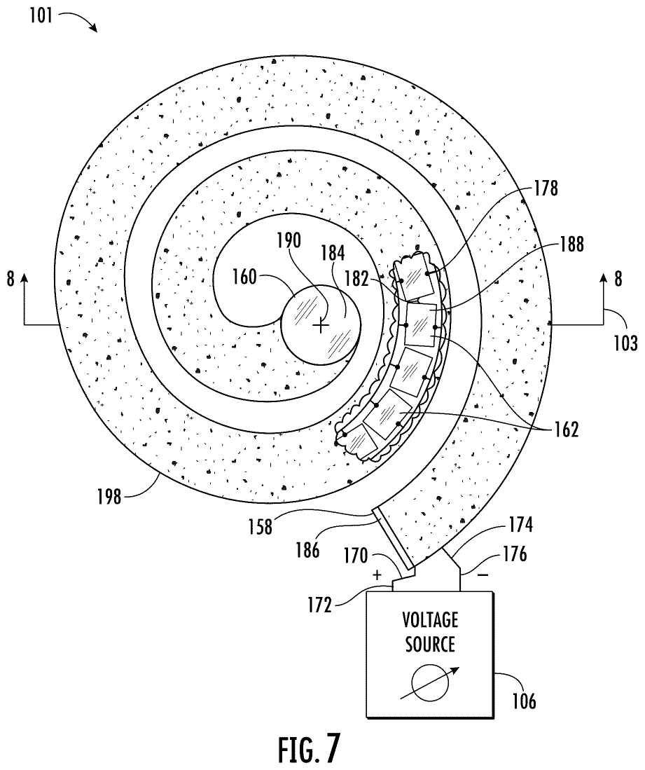

In the illustrated example, the lift pin body 156 is substantially linear along an entirety of its length between the contact feature 160 and the fixation feature 158. As will be appreciated by those of skill in the art in view of the present disclosure, the lift pin body 156 may be non-linear along at least a portion of its length, for example having an arcuate portion and/or a coiled or helical portion, and remain within the scope of the preset disclosure. Advantageously, the corrugated portions allows for the lift pin body to expand, bend, and twist in two-dimensions (as shown additionally in FIGS. 5 and 6) and three-dimensions (as shown in FIGS. 7-9). To further advantage, inclusion of a non-linear portion along the length of the lift pin body 156 enables employment of piezoelectric cells having relatively low piezoelectric constants. As will also be appreciated by those of skill in the art in view of the present disclosure, inclusion of a non-linear portion along the length of the lift pin body 156 also enables lift pin assemblies to provide relatively large length change for a given voltage applied to the lift pin assembly, for example length changes greater than a thickness of the end effector 132 (shown in FIG. 1).

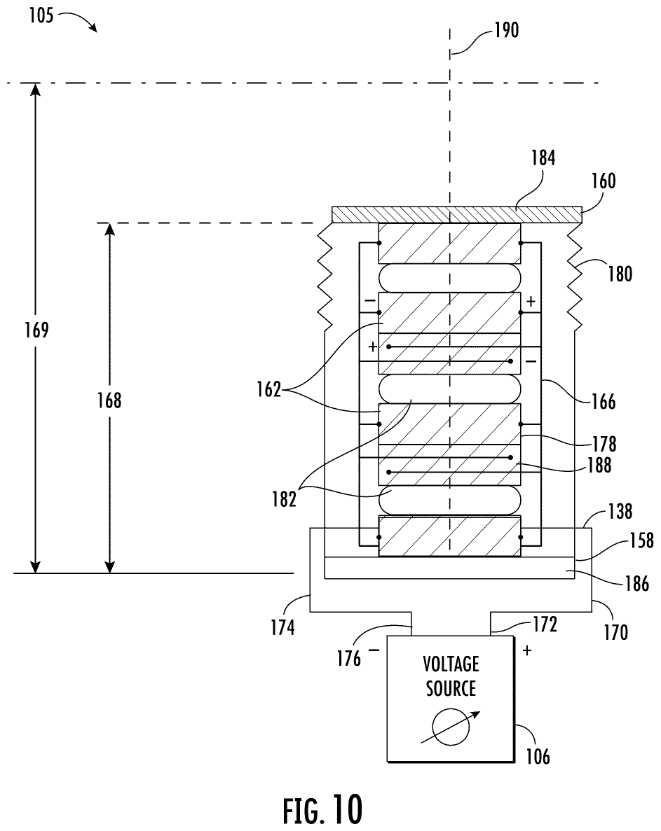

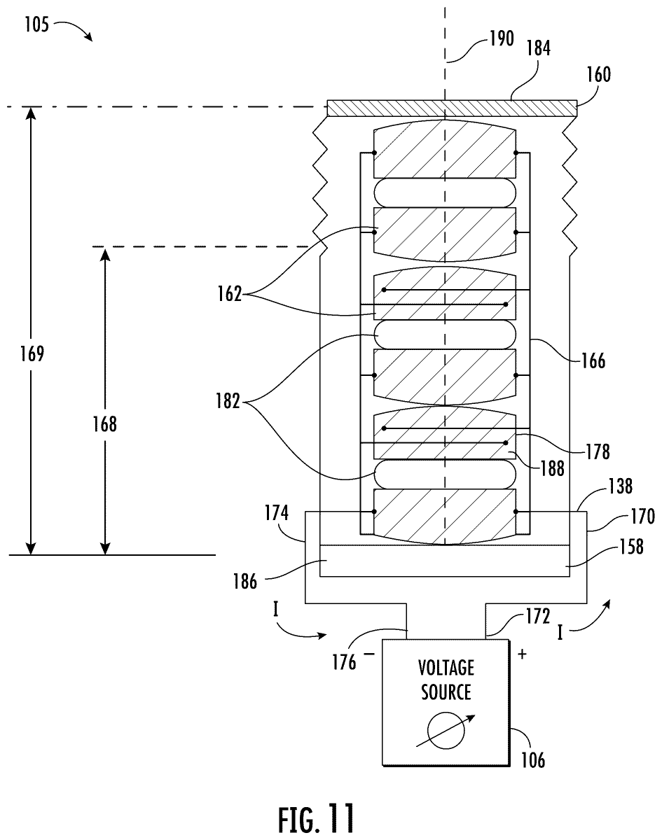

The plurality of piezoelectric cells 162 are stacked (e.g., longitudinally stacked) within the lift pin body 156 between the fixation feature 158 and the contact feature 160. It is contemplated that the individual ones of the plurality of piezoelectric cells 178 be constructed from a piezoelectric material 188 having a relatively high piezoelectric coefficient or piezoelectric modulus, such as ceramic materials like lead zirconate titanate (PZT) and polymeric composites including materials having relatively high piezoelectric coefficients. The individual ones of the plurality of piezoelectric cells 178 may be orientated in the same direction (as shown in FIGS. 3-9) or in opposite orientation (as shown in FIGS. 10 and 11). Additionally, the individual piezoelectric cells 178 may be coupled to the adjacent piezoelectric cells by one or more hinges 182 (as shown in FIGS. 5-11). As will be appreciated by those skilled in the art in view of the present disclosure, the one or more hinges 182 assist the plurality of piezoelectric cells 162 in remaining coupled as the plurality of piezoelectric cells 162 contour within an arcuate portion (as shown in FIGS. 5-9). Additionally, in the example where the individual piezoelectric cells have an opposite orientation (as shown in FIGS. 10 and 11) the one or more hinges 182 maintain the coupling between adjacent pairs of oppositely orientated individual piezoelectric cells 178.

The lead 138 is electrically connected to the plurality of piezoelectric cells 162 to exert an electrical field across individual ones of the plurality of piezoelectric cells 162. In this respect it is contemplated that the lead 138 couple an electrical bus 166 arranged within the lift pin body 156 to the external environment 12 (shown in FIG. 2) outside of the lift pin body 156. The lead 138 may further may extend through a aperture defined in the lift pin body 156 and/or the fixation feature 158 and electrically couple the plurality of piezoelectric cells 162 to the variable voltage source 106. For example, the lead 138 may couple the electrical bus 166 to a source lead 170 and therethrough to a positive terminal 172 of the variable voltage source 106, and a return lead 174 included in the lift pin assembly 102 may further electrically connect the electrical bus 166 to a negative terminal 176 of the variable voltage source 106. In such examples individual ones of the plurality of piezoelectric cells 162 may each be electrically coupled in parallel between the source lead 170 and the return lead 174 by the electrical bus 166.

Upon an applied voltage from the variable voltage source 106 to the plurality of piezoelectric cells 162, a potential difference exists across an individual piezoelectric cells. The potential difference induces physical the expansion of the individual piezoelectric cells 178 corresponding to magnitude of the potential difference and piezoelectric coefficient of the material forming the plurality of piezoelectric cells 162. The physical expansion of the plurality of piezoelectric cells 162 in turn causes force to be applied to a neighboring individual piezoelectric cells 178 and therethrough between the fixation feature 158 and the contact feature 160. The fixation feature 158 exerts an equal and opposite force to the sum of the individual piezoelectric cells 178 forces resulting in elongation of a corrugated portion 180 arranged along the lift pin body 156, for example at a location intermediate the contact feature 160 and the fixation feature 158 of the lift pin body 156. As will be appreciated by those of skill in the art in view of the present disclosure, electrically connecting the source lead 170 to the return lead 174 in parallel with the plurality of piezoelectric cells 162 may improve reliability of the lift pin assembly 102, for example by ensuring that the lift pin assembly 102 remains operational in the unlikely event that one or more of the plurality of piezoelectric cells 162 becomes electrically open.

In an alternative example, the source lead 170 may be electrically coupled to the positive terminal 172 of the variable voltage source 106 and the return lead 174 is electrically coupled to the negative terminal 176 of the variable voltage source 106, however the plurality of piezoelectric cells 162 may be electrically coupled in series with the source lead 170 and the return lead 174. In the series configuration, each individual piezoelectric cells 178 may experience similar current (I) across it as all the other individual piezoelectric cells 178. Coupling the plurality of piezoelectric cells 162 in series does increase the complexity of electrically coupling to adjacent piezoelectric cells 178, as the positive terminal of the next individual piezoelectric cell 178 is coupled to the negative terminal of the previous individual piezoelectric cell 178. As will be appreciated by those skilled in the art in view of the present disclosure, this increased complexity may allow for less electrical coupling overall as there is no longer a need for the individual piezoelectric cells to be electrically coupled to a common point (e.g. the source lead 170 or the return lead 174) via the electrical bus 166. While the source lead 170 and the return lead 174 are shown as being positioned proximal the fixation feature 158, other locations along the lift pin body 156 may be suitable for the source lead 170 and return lead 174 to be electrically coupled to the plurality of piezoelectric cells 162.

In the illustrated example the lift pin assembly 102 is substantially linear along the entirety of the lift pin body 156 and configured to lengthen and shorten according to voltage applied the lift pin assembly 102. As shown in FIG. 3, the lift pin body 156 may have a first length 168 when a first predetermined voltage is applied to the lift pin assembly 102. As shown in FIG. 4, the lift pin body 156 may have a second length 169 when a second predetermined voltage is applied to the lift pin assembly 102. The second predetermined voltage may be greater than the first predetermined voltage such that the plurality of piezoelectric cells 162 are relatively small in size, the lift pin body 156 thereby be shortened when the first predetermined voltage is applied to the lift pin assembly 102 as shown in FIG. 3, and that the plurality of piezoelectric cells 162 be enlarged and the lift pin body 156 thereby be elongated as shown in FIG. 4 when the second predetermined voltage is applied to the lift pin assembly 102, as comparatively shown with first length 168 to the second length 169 is indicated by the dashed line of FIG. 4. It is contemplated that the difference between the first length 168 and the second length 169 may be greater than 3 millimeters, or greater than 5 millimeters, or even greater than 10 millimeters, for example between 3 millimeters and about 15 millimeters. As will be appreciated by those of skill in the art in view of the present disclosure, length differences within these ranges enable to lift pin assembly 102 to cooperate with the end effector 132 (shown in FIG. 2) to seat and unseat the substrate 2 (shown in FIG. 2) from the substrate support 104 (shown in FIG. 2) while providing compactness to the chamber body 100 (shown in FIG. 1) housing the lift pin assembly 102.

In the illustrated example the lift pin body 156 is configured to direct length change along a substantially linear expansion axis 190. In this respect it is contemplated that the expansion axis 190 be orthogonal to either (or both) the contact feature 160 and the fixation feature 158. In further respect, it is contemplated that the expansion axis 190 extend through a center of the plurality of piezoelectric cells 162. As will be appreciated by those skilled in the art, change in length of the lift pin body 156 between the first length 168 to the second length 169 may be accomplished by confining elongation of the lift pin body 156 to the corrugated portion 180. As will also be appreciated by those of skill in the art in view of the present disclosure, expansion of the plurality of piezoelectric cells 162 due to the application of a voltage from the variable voltage source 106 to the lift pin assembly 102 may occur within both the corrugated portion 180 of the lift pin body 156 as well as one or more non-corrugated segment of the lift pin body 156, confining movement of the contact feature 160 to translation along the expansion axis 190.

With reference to FIGS. 5 and 6, a lift pin assembly 192 is shown. The lift pin assembly 192 is similar to the lift pin assembly 102 (shown in FIG. 3) and additionally includes a plurality of first linear portion 194, a second linear portion 196, an arcuate portion 198, and one or more hinges 182. The first linear portion 194 is connected to the fixation feature 158 and couples the arcuate portion 198 to the fixation feature 158. The arcuate portion 198 is connected to the first linear portion 194 and coupled therethrough to the fixation feature 158, and couples the second linear portion 196 to the first linear portion 194. The second linear portion 196 is connected to the arcuate portion 198, is coupled therethrough to the first linear portion 194, and couples the contact feature 160 to the arcuate portion 198. The first linear portion 194 is parallel to the second linear portion 196. Although shown and described herein as having two linear portions and a single arcuate portion it is to be understood and appreciated that the lift pin assembly 192 may have different numbers of linear portions and arcuate portions in other examples and remain within the scope of the present disclosure.

The first linear portion 194 is connected to the fixation feature 158 and couples the fixation feature 158 to the arcuate portion 198 of the lift pin assembly 192. The first linear portion 194 may be constructed out of a metal material or a stainless steel material. The first linear portion 194 may have one or more apertures for the source lead 170 and the return lead 174 to couple to the variable voltage source 106.

The arcuate portion 198 may be constructed out of a metal material or a stainless steel material, and guides the plurality of piezoelectric cells 162 around bends or curves. As will be appreciated by those skilled in the art, the plurality of piezoelectric cells 162 remain coupled through the arcuate portion 198 by the one or more hinges 182. The one or more hinges 182 couple the axially adjacent piezoelectric cells 178 around the curves and/or bends of the lift pin assembly 192 through laterally coupling the plurality of piezoelectric cells 162. The arcuate portion 198 may result in the lift pin assembly 192 appearing U-shaped or J-shaped.

The second linear portion 196 is connected to the contact feature 160 and couples the contact feature 160 to the arcuate portion 198 of the lift pin assembly 192. The second linear portion may be constructed out of a metal material or a stainless steel material. The second linear portion 196 may further include the corrugated portion 180.

The lift pin assembly 192 is shown at the first length 168 in FIG. 5 and the second length 169 in FIG. 6, and is arcuate in part between the contact feature 160 and the fixation feature 158. The plurality of piezoelectric cells 162 of FIG. 5 are in a shortened position, while the plurality of piezoelectric cells 162 of FIG. 6 are in a lengthened position, which results in the overall length of the lift pin assembly 192 to increase, when compared to the shortened position of FIG. 5. The change in length of the lift pin assembly 192 is a result of a voltage being applied to the plurality of piezoelectric cells 162 by the variable voltage source 106. The change in the length is indicated by the dashed line across the lift pin assembly 192, as shown in FIG. 6. The expansion of the plurality of piezoelectric cells 162 follows the expansion axis 190. The expansion axis 190 is orthogonal to the contact feature 160 and the fixation feature 158, and passes through the center of the plurality of piezoelectric cells 162. As will be appreciated by those skilled in the art, the shape of the lift pin assembly 192 allows for operation in two-dimensional space without adding additional volumetric requirements on the semiconductor processing system 118. Additional configurations are contemplated and remain within the scope of the present disclosure, such as S-shaped or serpentine.

With reference to FIGS. 7-9, a lift pin assembly 101 is shown. The lift pin assembly 101 is similar to lift pin assembly 102 (shown in FIG. 3) and additionally includes the arcuate portion 198. The arcuate portion 198 is connected to the fixation feature 158 and the contact feature 160, and is helical in part between the contact feature 160 and the fixation feature 158. The plurality of piezoelectric cells 162 are stacked within the arcuate portion 198 of the lift pin assembly 101. The plurality of piezoelectric cells 162 remain connected to the axially adjacent piezoelectric cells 178 by one or more hinges 182 (as shown in the tear out section of FIGS. 7-9). Although shown and described herein as having a single arcuate portion it is to be understood and appreciated that the lift pin assembly 101 may have multiple arcuate portions connected to an adjacent arcuate portion in other examples and remain within the scope of the present disclosure.

The arcuate portion 198 is connected to the contact feature 160 and the fixation feature 158. The arcuate portion 198 may be constructed out of a single arcuate portion or one or more arcuate portions connected together. The arcuate portion 198 may be constructed out of a metal material or a stainless steel material and may be configured to guide the plurality of piezoelectric cells 162 during expansion and contraction (e.g., by being rigid) around the bends or curves of the lift pin assembly 101. The plurality of piezoelectric cells 162 are stacked within the arcuate portion 198. As will be appreciated by those skilled in the art, the plurality of piezoelectric cells 162 remain coupled to the adjacent piezoelectric cell, through the arcuate portion, by one or more hinges 182.

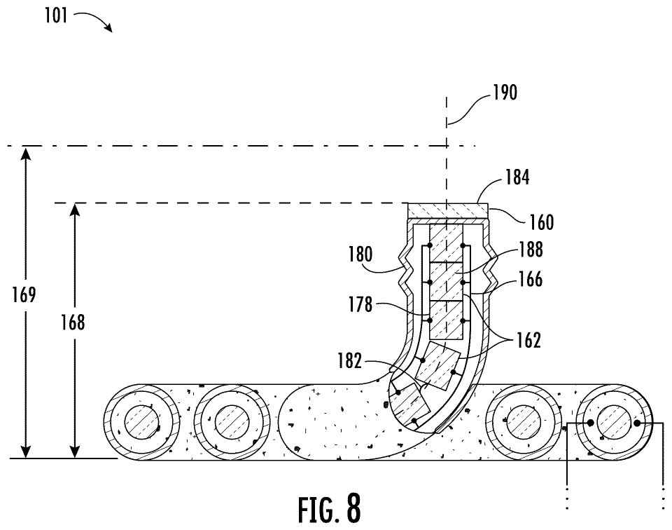

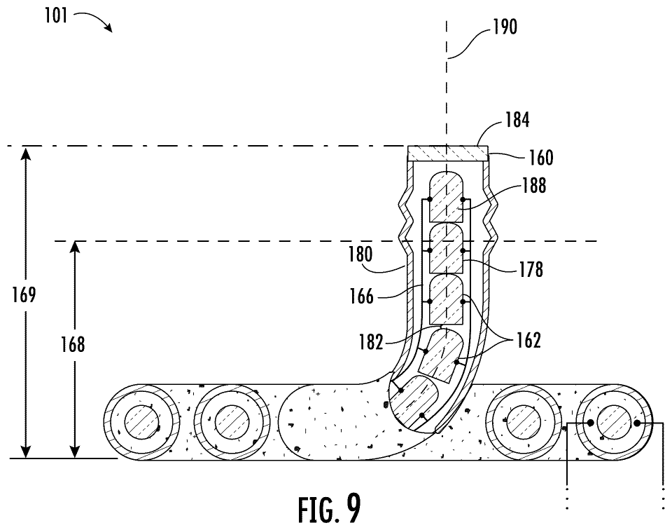

The plurality of piezoelectric cells 162 of FIGS. 7 and 8 are in a shortened position, while the plurality of piezoelectric cells 162 of FIG. 9 are in a lengthened position, which results in the overall length of the lift pin assembly 101 to increase. A cross-sectional line 103 is included in FIG. 7 directing the reader to FIGS. 8 and 9. The change in length of the lift pin assembly 101 is a result of a voltage being applied to the plurality of piezoelectric cells 162 by the variable voltage source 106. The change from the first length 168 to the second length 169 of the lift pin assembly 101 is shown in FIG. 9. The change in the length is indicated by the dashed line across the lift pin assembly 101, as shown in FIG. 9. The expansion of the plurality of piezoelectric cells 162 follows the expansion axis 190. The expansion axis 190 is orthogonal to the contact feature 160 and the fixation feature 158, and passes through the center of the plurality of piezoelectric cells 162. As will be appreciated by those skilled in the art, the shape of the lift pin assembly 101 allows for it to operate in three-dimensional space without adding additional volumetric requirements to the semiconductor processing system 118. The arcuate portion 198 is such that the lift pin assembly 101 resembles a coiled or helical like structure, and capable of operating in three-dimensional space while limiting volumetric requirements of the semiconductor processing system 118. As will be appreciated by those of skill in the art in view of the present disclosure, the increase in the number of individual piezoelectric cells 178, found in lift pin assembly 101, may result in an overall greater increased length when compared to the lift pin assembly 102 due to the increased number of individual piezoelectric cells 178. Additional configurations are contemplated and remain within the scope such increased number of turns of the arcuate portion 198 or the contact feature 160 being in a different plane of the lift pin assembly 101.

With reference to FIGS. 10 and 11, a lift pin assembly 105 is shown. The lift pin assembly 105 is similar to lift pin assembly 101 (shown in FIG. 3) and additionally includes a plurality of individually reversed polarity piezoelectric cells 178 of the plurality of piezoelectric cells 162. The plurality of individually reversed polarity piezoelectric cells 178 are axially stacked among the plurality of piezoelectric cells 162, are coupled thereto by one or more hinges 182, and are configured to expand in a direction axially opposite that the of the plurality of piezoelectric cells 162. It is contemplated that electrical connectivity of the electrical bus 166 to the plurality of piezoelectric cells 162 may be such that polarity of the voltage applied to the lift pin assembly 105 is reversed on the plurality of individually reversed polarity piezoelectric cells 178 when voltage is applied to the lift pin assembly 105. As will be appreciated by those skilled in the art in view of the present disclosure, expansion associated with voltage increase thereby cooperates with the hinges 182 to elongate the lift pin body 156, contraction associated with voltage decrease also cooperates with the hinges 182 to shorten the lift pin body 156. Advantageously, inclusion of the hinges 182 may limit off-axis elongation of the lift pin assembly 105, enabling greater length change than otherwise possible.

The lift pin assembly 105 is shown at the first length 168 in FIG. 10 and the second length 169 in FIG. 11. The plurality of piezoelectric cells 162 of FIG. 10 are axially stacked in a shortened position, while the plurality of piezoelectric cells 162 of FIG. 11 are in a lengthened position, which results in the overall length of the lift pin assembly 105 to increase, when compared to the shortened position of FIG. 10. The change in length of the lift pin assembly 105 is a result of a voltage being applied to the plurality of piezoelectric cells 162 by the variable voltage source 106. The change in the length is indicated by the dashed line across the lift pin assembly 105, as shown in FIG. 11. The expansion of the plurality of piezoelectric cells 162 follows the expansion axis 190. The expansion axis 190 is orthogonal to the contact feature 160 and the fixation feature 158, and passes through the center of the plurality of piezoelectric cells 162. The axially adjacent piezoelectric cells 178 are arranged such that the application of an applied voltage results in the convex portions of the plurality of piezoelectric cells 162 making contact. For the portion of the axially adjacent piezoelectric cells 178 that do not undergo expansion they are coupled to the next axially adjacent piezoelectric cells 178 by one or more hinges 182. As will be appreciated by those skilled in the art, the orientation of the plurality of piezoelectric cells 162 allow the lift pin assembly 105 to remain compact within the semiconductor processing system 118. While shown and described herein as having an alternating plurality of piezoelectric cell orientation, additional configurations are contemplated and remain within the scope such as groups of oppositely orientated piezoelectric cells or non-uniform distribution of oppositely orientated piezoelectric cells.

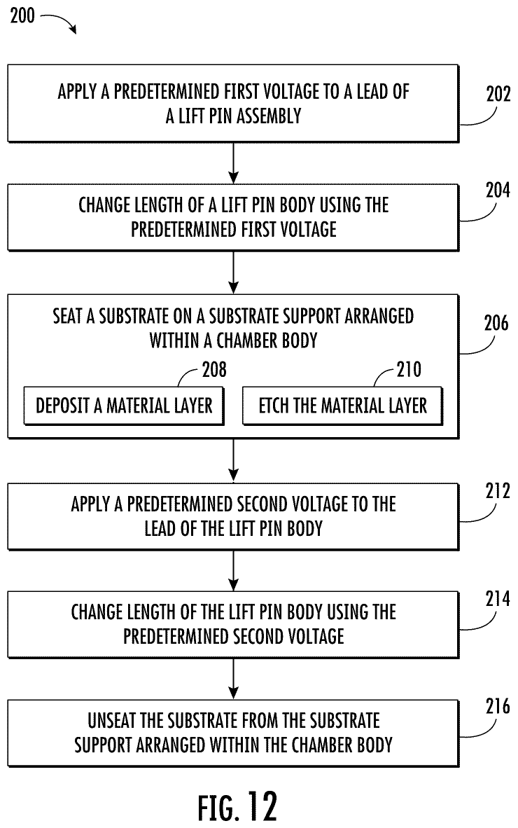

With reference to FIGS. 12-14, the method 200 of transferring substrates in the semiconductor processing systems using lift pin assemblies is shown according to an example of the present disclosure. As shown in FIG. 12, the method 200 includes applying a predetermined first voltage to a lead of a lift pin assembly, e.g., the source lead 170 (shown in FIGS. 3-11), as shown with box 202, which results in changing the length of the lift pin body, e.g., the first length 168 (shown in FIG. 3), as shown with box 204. The method 200 further includes seating the substrate on a substrate support arranged within a chamber body such that a material layer may be deposited onto the substrate and/or an etchant may be applied to the material layer, e.g., seating the substrate 2 (shown in FIG. 1) on the substrate support 104 (shown if FIG. 1) arranged within the chamber body 100 (shown in FIG. 1) such that the material layer 10 (shown in FIG. 2), as shown with boxes 206-210. Seating 206 the substrate on the substrate support may also include opening the gate valve coupling a substrate transfer robot with an end effector to the chamber body, e.g., the gate valve 130 (shown in FIG. 2) coupling the substrate transfer robot with an end effector 132 (shown in FIG. 2) to the chamber body, and transferring a singular substrate into the chamber body, as shown with box 206.

The method 200 further includes applying a predetermined second voltage to the lead of the lift pin assembly, e.g., the source lead 170 (shown in FIG. 1), as shown with box 212, which results in changing the length of the lift pin body, e.g., the second length 169 (shown in FIG. 4), as shown with box 214. The method 200 may further include unseating the substrate from the substrate support arranged within the chamber body as shown with box 216. Unseating 216 the substrate from the substrate support may include opening the gate valve coupling the substrate transfer robot with an end effector to the chamber body, and removing the singular substrate from the chamber body, as shown with box 216. It is contemplated that a semiconductor device may be fabricated using the material layer deposited onto the substrate and/or the substrate subsequent to removal of material from the substrate with the etchant, such as a memory device or a logic device having a three-dimensional (3D) architecture. The material layer deposition and the etchant may be applied within the same chamber body or the substrate may be transferred to a different chamber body for either the material deposition or the etchant. In this non-limiting example, both may deploy the method described herein.

As shown in FIG. 13, the method 200 may include seating a substrate on a substrate support within a loadlock chamber body, e.g., the chamber body 100 (shown in FIG. 1), where heating the substrate and/or chilling the substrate may take place, as shown with boxes 218-222. The method 200 may further include unseating the substrate from substrate support in the loadlock chamber body and thereafter transferring the substrate into and seating the substrate therein on a substrate support within a deposition chamber, e.g., the chamber body 100 (shown in FIG. 1), as shown with box 224. The method 200 may further include heating the substrate to a predetermined material layer deposition temperature, for example using a heater element seated on the substrate support, and depositing a material layer onto the substrate using a flow of a material layer precursor provided to the deposition chamber body, e.g., the flow of material layer precursor 16 (as shown in FIG. 2), as shown with box 226 and box 228. The method 200 may further include unseating the substrate from the substrate support within the deposition chamber and thereafter transferring the substrate from the deposition chamber to the substrate support within the loadlock chamber, as shown with box 230 and box 232.

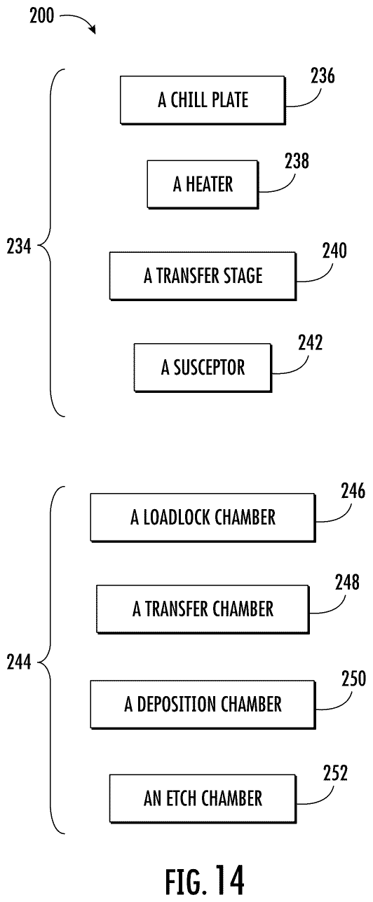

As shown in FIG. 14, it is contemplated the lift pin assembly may be slidably received in different types of substrates support in a semiconductor processing system, e.g., the semiconductor processing system 118 (shown in FIG. 2), as shown with bracket 234. For example, the lift pin assembly may be slidably received in a chill plate included in the semiconductor processing system as shown in box 236. The lift pin assembly may be slidably received in a heater included in the semiconductor processing system, as shown with box 238. It is also contemplated that the lift pin assembly may be slidably received in a transfer stage or a susceptor of the semiconductor processing system, as shown with box 240 and box 242. It is also contemplated that the lift pin assembly may be included in different modules of the semiconductor processing system, as shown with bracket 244. For example, the lift pin assembly may be included in a loadlock chamber of the semiconductor processing system, as shown with box 246. The lift pin assembly may be included in a transfer chamber of the semiconductor processing system, as shown with box 248. It is further contemplated that the lift pin assembly may be included in a deposition chamber or an etch chamber of the semiconductor processing system, as shown with box 250 and box 252.

Lift pins can be used in semiconductor processing systems to transfer substrates, for example by seating and unseating substrates from substrate supports in the semiconductor processing system, such as using a mechanical actuator and a motor. While generally acceptable for their intended purpose, mechanical actuators and motors may require periodic maintenance, limiting throughput of the semiconductor processing system. The mechanical actuators and motor may also require space within the semiconductor processing system, increasing size of the module including the mechanical actuator and/or motor, increasing size and potentially also reducing throughput in settings wherein the mechanical actuator and/or motor inhabits evacuated space.

In examples described, solid-state lift pin assemblies are provided. The solid-state lift pin assemblies include piezoelectric cells to seat and unseat substrates within the semiconductor processing system, eliminating the need for mechanical actuators and/or motors and enabling modules of the semiconductor processing system to be relatively compact. In certain examples of the present disclosure, lift pin assembles having arcuate portions are provided, simplifying packaging of the lift pin assembly within chambers and modules of the semiconductor processing and further limiting size of modules of the semiconductor processing system.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A lift pin assembly, comprising:
a lift pin body having:
a contact feature defined on a first end of the lift pin body; and
a fixation feature longitudinally opposite the contact feature;
a plurality of piezoelectric cells stacked within the lift pin body between the fixation feature and the contact feature; and
a lead electrically connected to the plurality of piezoelectric cells and extending to an external environment outside of the lift pin body to change a length of the lift pin body between a first length and a second length using a voltage applied to the lead.

2. The lift pin assembly of claim 1, wherein the lift pin body is linear along an entirety of the length of the lift pin body between the contact feature and the fixation feature.

3. The lift pin assembly of claim 1, wherein the lift pin body is arcuate at least in part between the contact feature and the fixation feature or helical at least in part between the contact feature and the fixation feature.

4. The lift pin assembly of claim 2, wherein the lift pin body is corrugated.

5. The lift pin assembly of claim 1, wherein the lift pin body further comprises:
a first linear portion,
an arcuate portion extending from the first linear portion, and
a second linear portion extending from the arcuate portion and parallel to the first linear portion, the second linear portion corrugated along at least a segment of its length, the second linear portion formed from a shape memory alloy.

6. The lift pin assembly of claim 1, further comprising the plurality of piezoelectric cells longitudinally stacked within the lift pin body.

7. The lift pin assembly of claim 6, wherein one or more of the plurality of axially adjacent piezoelectric cells is coupled by a hinge.

8. The lift pin assembly of claim 1, wherein the plurality of piezoelectric cells comprises a crystalline material, a ceramic material, or a polymeric material.

9. The lift pin assembly of claim 1, wherein the plurality of piezoelectric cells are electrically coupled in parallel between the lead and a return terminal.

10. The lift pin assembly of claim 1, wherein the contact feature comprises silicon nitride (SiN), aluminum oxide (Al₂O₃), quartz, and diamond-like carbon.

11. A semiconductor processing system, comprising:
a chamber body having a hollow interior;
a substrate support arranged within the interior of the chamber body and defining a lift pin aperture therethrough;
a lift pin assembly arranged within the lift pin aperture, the lift pin assembly comprising:
a lift pin body having:
a contact feature defined on a first end of the lift pin body; and
a fixation feature longitudinally opposite the contact feature;
a plurality of piezoelectric cells stacked within the lift pin body between the fixation feature and the contact feature; and
a lead electrically connected to the plurality of piezoelectric cells and extending to an external environment outside of the lift pin body to change a length of the lift pin body between a first length and a second length using a voltage applied to the lead; and
a controller operably coupling a voltage source to the lift pin assembly, the controller responsive to instructions recorded on a memory included on a non-transitory machine-readable medium to:
apply a predetermined first voltage to the lead of the lift pin assembly;
change the length of the lift pin body from the first length using the predetermined first voltage applied to the lead of the lift pin assembly;
apply a predetermined second voltage to the lead of the lift pin assembly; and
change the length of the lift pin body to the second length using the predetermined second voltage applied to the lead of the lift pin assembly.

12. The semiconductor processing system of claim 11, wherein the chamber body is a loadlock chamber, a transfer chamber, a deposition chamber, or an etch chamber.

13. The semiconductor processing system of claim 11, wherein the lift pin assembly is one of a plurality of lift pin assemblies arranged within the chamber body and slidably received in lift pin apertures defined within the substrate support, and wherein the substrate support is a transfer stage, a chill plate, a heater, or a susceptor.

14. A substrate transfer method, comprising:
at a lift pin assembly, including a lift pin body having a contact feature defined on a first end of the lift pin body, a fixation feature longitudinally opposite the contact feature, a plurality of piezoelectric cells stacked within the lift pin body between the fixation feature and the contact feature, and a lead electrically connected to the plurality of piezoelectric cells and extending to an external environment outside of the lift pin body;
applying a predetermined first voltage to the lead of the lift pin assembly;
changing a length of the lift pin body from a first length using the predetermined first voltage applied to the lead of the lift pin assembly;
applying a predetermined second voltage to the lead of the lift pin assembly; and
changing the length of the lift pin body to a second length using the predetermined second voltage applied to the lead of the lift pin assembly.

15. The method of claim 14, further comprising seating the substrate on a substrate support arranged within a chamber body of a semiconductor processing system during change of the length of the lift pin body from the first length to the second length.

16. The method of claim 15, wherein the chamber body is a deposition chamber, and wherein the method further comprises depositing a material layer onto the substrate while the predetermined second voltage is applied to the lead.

17. The method of claim 15, wherein the chamber body is an etch chamber, and wherein the method further comprises removing material from the substrate while the predetermined second voltage is applied to the lead.

18. The method of claim 15, wherein the substrate support is a chill plate, and wherein the method further comprises chilling the substrate on the chill plate while the predetermined second voltage is applied to the lead.

19. The method of claim 15, wherein the substrate support is a heater, and wherein the method further comprises heating the substrate while the predetermined second voltage is applied to the lead.

20. The method of claim 14, wherein the lift pin assembly is arranged within a loadlock chamber body, and wherein the method further comprises:
prior to applying the predetermined second voltage to the lead, supporting the substrate above the lift pin assembly by driving a first end effector carrying the substrate into the loadlock chamber body such that the predetermined second voltage thereafter causes the substrate to transfer from the first end effector to the contact feature of the lift pin assembly;
withdrawing the first end effector from the loadlock chamber body;
driving a second end effector into the loadlock chamber body; and
changing voltage applied to the lead from the predetermined second voltage, whereby further change in the length of the lift pin body transfers the substrate from the contact feature to the second end effector.
